(19) United States
(12) Patent Application Publication
(10) Pub. No.: US 2017/0117465 A1
(43) Pub. Date: Apr. 27, 2017

(54) Resistive Random Access Memory

(71) Applicant: NATIONAL SUN YAT-SEN UNIVERSITY, Kaohsiung City (TW)

(72) Inventors: Ting-Chang Chang, Kaohsiung City (TW); Kuan-Chang Chang, Kaohsiung City (TW); Tsung-Ming Tsai, Kaohsiung City (TW); Chih-Cheng Shih, Kaohsiung City (TW); Chih-Hung Pan, Kaohsiung City (TW)

(21) Appl. No.: 14/957,658

(22) Filed: Dec. 3, 2015

(30) Foreign Application Priority Data
Oct. 26, 2015 (TW) 104135115

(51) Int. Cl. H01L 45/00

(52) U.S. Cl. CPC H01L 45/08; H01L 45/1233; H01L 45/146; H01L 45/1253; H01L 45/1246

(57) ABSTRACT

A resistive random access memory does not encounter the undesired effects caused by sneak current which occurs when a conventional resistive random access memory operates in an integrated circuit. The resistive random access memory includes a first electrode layer, a first insulating layer, an oxygen-containing layer, a second insulating layer and a second electrode layer. The first insulating layer is arranged on the first electrode layer. The oxygen-containing layer is arranged on the first insulating layer and includes an oxide doped with a metal element. The metal element does not exceed 10% of the oxygen-containing layer. The second insulating layer is arranged on the oxygen-containing layer, and the second electrode layer is arranged on the second insulating layer. In this arrangement, the undesired effects caused by sneak current can be effectively eliminated.

### CROSS REFERENCE TO RELATED APPLICATIONS

The application claims the benefit of Taiwan application serial No. 104135115, filed on Oct. 26, 2015, and the subject matter of which is incorporated herein by reference.

### BACKGROUND OF THE INVENTION

1. Field of the Invention

The present disclosure generally relates to a resistive random access memory and, more particularly, to a complementary resistive random access memory.

2. Description of the Related Art

Memory devices have been widely used in electronic products. Among various types of memory devices, the resistive random access memory has the advantages such as low operational voltage, fast retrieving speed and high compactness. Thus, the resistive random access memory has the potential to replace the conventional flash memory and dynamic random access memory, and may become the mainstream of the memory devices in the next generation.

A conventional complementary resistive (CRS) switching memory may form a “metal/dielectric(insulating)/metal/dielectric/metal (MIMIM)” structure. In the structure, an electric field is applied to cause a redox reaction of the metal filament through the oxygen ions contained in the two insulating layers. As a result, a high resistance state and a low resistance state may be formed for the purpose of storing digital data. One embodiment of such a conventional complementary resistive switching memory may be seen in “Analysis of Complementary RRAM Switching” in IEEE ELECTRON DEVICE LETTERS, VOL. 33, NO. 8, as published by Dirk J. Wouters, Leqi Zhang, Andrea Fantini, Robin Degraeve, Ludovic Goux, Yang Y. Chen, Bogdan Govoreanu, Gouri S. Kar, Guido V. Groeseneken, and Malgorzata Jurczak on August 2012.

When a positive or negative bias is applied to the conventional complementary resistive switching memory, one of the resistive random access memories may perform a “setting” process, whereas the other one may perform a “resetting process.” Due to the asymmetric voltages between the “setting” process and the “resetting” process, a memory window may be formed on the characteristic curve, as indicated by the area labeled “W” in FIG. 1. This can eliminate the undesired effects caused by the sneak current which occurs when the conventional resistive random access memories operate in an integrated circuit. However, the conventional complementary resistive switching memory requires a pure gold material to be plated between the two insulating layers, leading to a complex manufacturing procedure and a high cost.

In light of this, it is necessary to improve the conventional complementary resistive switching memory.

### SUMMARY OF THE INVENTION

It is therefore the objective of this disclosure to provide a resistive random memory which does not require any pure gold material to be plated between the two insulating layers thereof.

In an embodiment of the disclosure, a resistive random access memory including a first electrode layer, a first insulating layer, an oxygen-rich layer, a second insulating layer and a second electrode layer is disclosed. The first insulating layer is arranged on the first electrode layer. The oxygen-rich layer is arranged on the first insulating layer and includes an oxide doped with a metal element. The metal element does not exceed 10% of the oxygen-rich layer. The second insulating layer is arranged on the oxygen-rich layer, and the second electrode layer is arranged on the second insulating layer.

In a form shown, the metal element is selected from one of gadolinium, titanium, zirconium, hafnium, tantalum and tungsten.

In the form shown, the oxide is selected from one of silicon dioxide and hafnium dioxide.

In the form shown, the oxygen-rich layer has a thickness of 5-15 nm, with 10 nm being preferred.

In the form shown, both the first and second insulating layers have a thickness of 10-30 nm. Both the first insulating layer and the second insulating layer are made of zinc oxide, indium trioxide, gallium trioxide or stannic oxide.

In the form shown, both the first electrode layer and the second electrode layer are made of platinum or titanium nitride.

In the above, by involving the oxygen ions and the metal element of the oxygen-rich layer in the switching process of the resistance states, the resistive random memory does not encounter the undesired effects caused by the sneak current which occurs when the conventional resistive random memory operates in an integrated circuit. In addition, a pure gold material does not need to be plated between the two insulating layers thereof Advantageously, the production cost can be reduced as compared with the conventional complementary resistive switching memory.

### BRIEF DESCRIPTION OF THE DRAWINGS

The present disclosure will become more fully understood from the detailed description given hereinafter and the accompanying drawings which are given by way of illustration only, and thus are not limitative of the present disclosure, and wherein:

FIG. 1 shows a characteristic curve of a conventional complementary resistive switching memory.

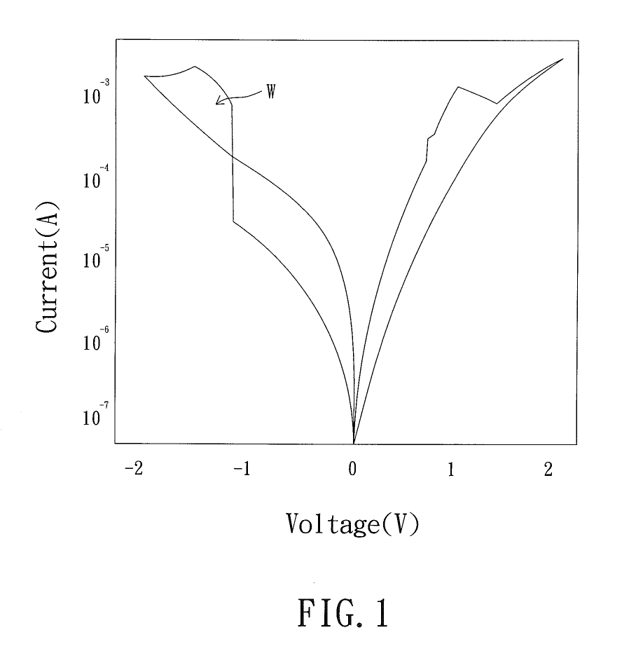

FIG. 2 shows a structure of a resistive random memory according to an embodiment of the disclosure.

FIG. 3 shows a characteristic curve of the resistive random memory according to the embodiment of the disclosure.

In the various figures of the drawings, the same numerals designate the same or similar parts. Furthermore, when the terms “first”, “second”, “third”, “fourth”, “inner”, “outer”, “top”, “bottom”, “front”, “rear” and similar terms are used hereinafter, it should be understood that these terms have reference only to the structure shown in the drawings as it would appear to a person viewing the drawings, and are utilized only to facilitate describing the disclosure.

### DETAILED DESCRIPTION OF THE INVENTION

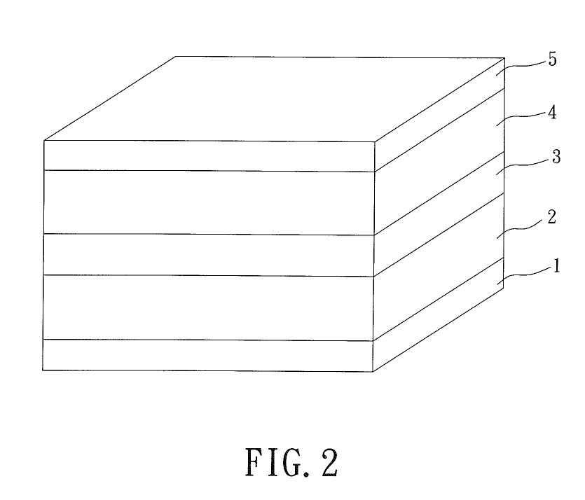

FIG. 2 shows a structure of a resistive random memory according to an embodiment of the disclosure. The resistive random memory may include a first electrode layer 1, a first insulating layer 2, an oxygen-rich layer 3, a second insulating layer 4 and a second electrode layer 5. The first insulating layer 2 is arranged on the first electrode layer 1, and the oxygen-rich layer 3 is arranged on the first insulating layer 2. The oxygen-rich layer 3 may be formed by doping an oxide with a metal element. The metal element does not exceed 10% of the oxygen-rich layer 3 (for example, does not exceed 10% of the oxygen-rich layer 3 in mole ratio). The second insulating layer 4 is arranged on the oxygen-rich layer 3, and the second electrode layer 5 is arranged on the second insulating layer 4.

In the embodiment, both the first electrode layer 1 and the second electrode layer 5 may be made of a material with excellent electricity conductivity, such as platinum or titanium nitride. Both the first insulating layer 2 and the second insulating layer 4 may be made of a material with an insulation function, such as zinc oxide (ZnO), indium trioxide (In₂O₃), gallium trioxide (Ga₂O₃) or stannic oxide (SnO). The metal element of the oxygen-rich layer 3 may have excellent electricity conductivity, such as gadolinium (Gd), titanium (Ti), zirconium (Zr), hafnium (Hf), tantalum (Ta) or tungsten (W). The oxide of the oxygen-rich layer 3 may be silicon dioxide (SiO₂) or hafnium dioxide (HfO₂). In addition, the oxygen-rich layer 3 may have a thickness of 5-15 nm, with 10 nm being preferred. Both the first insulating layer 2 and the second insulating layer 4 may have a thickness of 10-30 nm, but is not limited thereto.

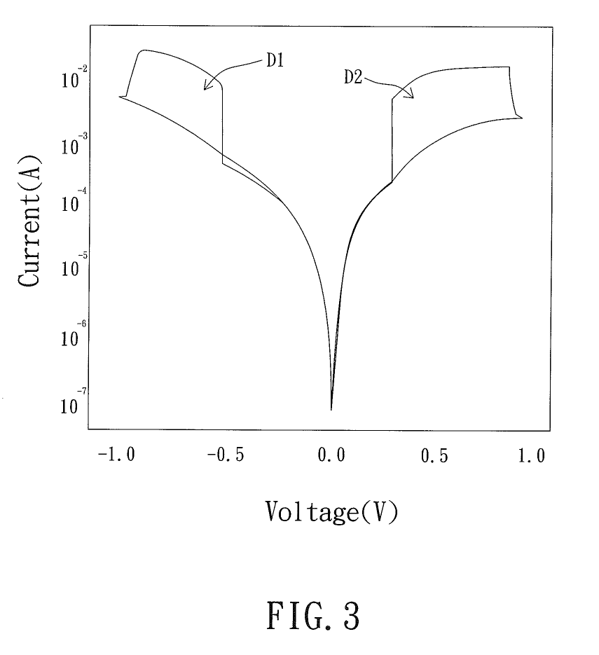

During the use of the resistive random memory according to the embodiment of the disclosure, a bias signal may be applied between the first electrode layer 1 and the second electrode layer 5. The bias signal may be a pulse width modulation (PWM) signal. The polarity, the magnitude, the duty cycle, and the frequency (the number of pulses per unit of time) of the PWM signal are adjustable. After the initial forming process, an electricity field may be applied to conduct a redox reaction of the metal element of the oxygen-rich layer 3 through the oxygen ions of the oxygen-rich layer 3. The oxygen ions may have high/low resistance state of bipolar switching characteristic curve as shown in FIG. 3.

Referring to FIG. 3 again, the characteristic curve of the oxygen ions of the oxygen-rich layer 3 and the characteristic curve of the metal element of the oxygen-rich layer 3 may be complementary. Thus, when the bias signal is positive, the oxygen ions and the metal element of the oxygen-rich layer 3 may exhibit a “setting” effect as the voltage increases, whereas the first insulating layer 2 and the second insulating layer 4 may exhibit a “resetting” effect as the voltage increases. To the contrary, when the bias signal is negative, the oxygen ions and the metal element of the oxygen-rich layer 3 may exhibit a “resetting” effect as the voltage decreases, whereas the first insulating layer 2 and the second insulating layer 4 may exhibit a “setting” effect as the voltage decreases.

Since both the first insulating layer 2 and the second insulating layer 4 may form the “setting” and “resetting” effects (such as switching between the high and low resistance states), exhibit a bipolar switching characteristic, and include two memory windows D1 and D2, the characteristic curve of the resistive random access memory according to the embodiment of the disclosure (as shown in FIG. 3) does not have the undesired effects caused by the sneak current which occurs when the conventional resistive random access memory operates in an integrated circuit. As another advantage, the resistive random access memory according to the embodiment of the disclosure has a low forming voltage and a low malfunction rate.

In addition to the elimination of the undesired effects caused by the sneak current, the resistive ransom access memory according to the embodiment of the disclosure does not require a pure metal material to be plated between the two insulating layers during the production process. In other words, the first insulating layer 2, the oxygen-rich layer 3 and the second insulating layer 4 may be formed in similar processes. Due to the similarity in the production process, the first insulating layer 2, the oxygen-rich layer 3 and the second insulating layer 4 may be formed in an one-off process to simplify the production procedure. As such, the resistive ransom access memory according to the embodiment of the disclosure has a reduced manufacturing cost.

Referring to FIG. 2 again, the resistive ransom access memory according to the embodiment of the disclosure is formed by arranging the first insulating layer 2 on the first electrode layer 1, arranging the oxygen-rich layer 3 on the first insulating layer 2, arranging the second insulating layer 4 on the oxygen-rich layer 3, and arranging the second electrode layer 5 on the second insulating layer 4. In the structure, the oxygen-rich layer 3 may be formed by doping an oxide with a metal element. The metal element may be gold and does not exceed 10% of the oxygen-rich layer 3. The oxygen-rich layer 3 may have a thickness of 5-15 nm, with 10 nm being preferred. As such, the resistive ransom access memory according to the embodiment of the disclosure may form the “setting” and “resetting” effects by involving the oxygen ions and the metal element in the switching process of the resistance states. Thus, the characteristic curve of the resistive ransom access memory according to the embodiment of the disclosure may switch between the high and low resistance states, exhibit a bipolar switching mechanism, and include two memory windows. Advantageously, the resistive random access memory according to the embodiment of the disclosure does not encounter the undesired effects caused by the sneak current which occurs when the conventional resistive random access memory operates in an integrated circuit.

Moreover, the resistive random access memory according to the embodiment of the disclosure does not require a pure metal material to be plated between the two insulating layers. As such, the production cost is reduced, which improves over the conventional resistive random access memory in term of cost.

Although the disclosure has been described in detail with reference to its presently preferable embodiments, it will be understood by one of ordinary skill in the art that various modifications can be made without departing from the spirit and the scope of the disclosure, as set forth in the appended claims.

1. (canceled)

2. A resistive random access memory comprising:
a first electrode layer;
a first insulating layer arranged on the first electrode layer;
an oxygen-containing layer arranged on the first insulating layer and comprising an oxide doped with a metal element, wherein the metal element does not exceed 10% of the oxygen-containing layer, wherein the metal element is selected from one of gadolinium, zirconium, tantalum and tungsten;
a second insulating layer arranged on the oxygen-containing layer; and
a second electrode layer arranged on the second insulating layer.

3. The resistive random access memory as claimed in claim 2, wherein the oxide is selected from one of silicon dioxide and hafnium dioxide.

4. The resistive random access memory as claimed in claim 2, wherein the oxygen-containing layer has a thickness of 5-15 nm.

5. The resistive random access memory as claimed in claim 4, wherein the thickness of the oxygen-containing layer is 10 nm.

6. The resistive random access memory as claimed in claim 2, wherein both the first insulating layer and the second insulating layer have a thickness of 10-30 nm.

7. The resistive random access memory as claimed in claim 2, wherein both the first electrode layer and the second electrode layer are made of titanium nitride or platinum.

8. The resistive random access memory as claimed in claim 2, wherein both the first insulating layer and the second insulating layer are made of zinc oxide, indium trioxide, gallium trioxide or stannic oxide.
